(19) United States
(12) Patent Application Publication
(10) Pub. No.: US 2026/0321947 A1
(43) Pub. Date: Oct. 15, 2026

(54) HIGH-FREQUENCY SIGNAL TRANSMISSION LINE AND ELECTRONIC DEVICE

(71) Applicant: Murata Manufacturing Co., Ltd., Nagaokakyo-shi (JP)

(72) Inventors: Nobuo IKEMOTO, Nagaokakyo-shi (JP); Yasuhiro OUCHI, Nagaokakyo-shi (JP); Masanori OKAMOTO, Nagaokakyo-shi (JP)

(21) Appl. No.: 19/697,765

(22) Filed: Jun. 4, 2026

Related U.S. Application Data
(63) Continuation of application No. PCT/JP2024/039618, filed on Nov. 7, 2024.

(30) Foreign Application Priority Data
Dec. 6, 2023 (JP) 2023-206247

(51) Int. Cl. H01P 3/08; H05K 1/02; H05K 1/11

(52) U.S. Cl. CPC H01P 3/087; H05K 1/024; H05K 1/0242; H05K 1/115; H05K 2201/0191; H05K 2201/0195; H05K 2201/0394; H05K 2201/093

(57) ABSTRACT

A high-frequency signal transmission line includes a resin stacked portion in which a first resin layer and a second resin layer are stacked, a signal conductor pattern on the first resin layer, and a ground conductor layer facing the signal conductor pattern with the resin stacked portion interposed therebetween. Openings are located in the first resin layer at positions along the signal conductor pattern in the resin stacked portion, so that hollow portions are provided in the resin stacked portion at these openings. In the second resin layer in contact with the first resin layer in which the opening is located, a maximum thickness and a minimum thickness are different at the opening located in the first resin layer, so that the second resin layer in contact with the first resin layer adheres to a portion of the end surface at the opening of the first resin layer.

### CROSS REFERENCE TO RELATED APPLICATIONS

This application claims the benefit of priority to Japanese Patent Application No. 2023-206247 filed on Dec. 6, 2023 and is a Continuation Application of PCT Application No. PCT/JP2024/039618 filed on Nov. 7, 2024. The entire contents of each application are hereby incorporated herein by reference.

### BACKGROUND OF THE INVENTION

### 1. Field of the Invention

The present invention relates to high-frequency signal transmission lines and electronic devices including the same.

### 2. Description of the Related Art

International Publication WO 2022/113591 A discloses a transmission line having a suspended structure in which a signal line is formed in a resin layer and hollow portions are formed above and below the signal line. In addition, the side surface of the adhesive layer in contact with the hollow portion is configured to have a concave shape.

### SUMMARY OF THE INVENTION

In the high-frequency signal transmission line described in International Publication WO 2022/113591 A, since the adhesive layer is in contact with only the upper and lower surfaces of the base material layer, the bonding strength of the stacked body is weak in a structure in which a hollow portion is formed. In addition, since there are no adhesive layers above and below the hollow portion, the strength of the upper and lower layers of the hollow portion is weak. Therefore, when the vicinity of the hollow portion of the high-frequency signal transmission line is deformed by an external force on the high-frequency signal transmission line, the electrical characteristics of the high-frequency signal transmission line become unstable.

Therefore, example embodiments of the present invention provide high-frequency signal transmission lines that each maintain high strength of a resin stacked portion and a hollow portion and has stable electrical characteristics, and electronic devices including the high-frequency signal transmission lines.

A high-frequency signal transmission line according to an example embodiment of the present disclosure includes a resin stacked portion in which a single or plurality of first resin layers and a single or plurality of second resin layers are stacked, a signal conductor pattern in contact with at least a single first resin layer of the single or the plurality of first resin layers, and a ground conductor layer facing the signal conductor pattern with a portion or an entirety of the resin stacked portion interposed therebetween, in which a hollow portion is provided in the resin stacked portion at an opening in at least the single first resin layer of the first resin layers at a position along the signal conductor pattern in the resin stacked portion, and in the second resin layer in contact with the first resin layer including the opening, the second resin layer in contact with the first resin layer adheres to a portion of an end surface in the opening of the first resin layer including the opening.

According to example embodiments of the present invention, it is possible to obtain high-frequency signal transmission lines each having high resistance to stress applied from the outside and stable electrical characteristics, and electronic devices including the high-frequency signal transmission lines.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a plan view (upper portion) illustrating a high-frequency signal transmission line 101 according to a first example embodiment, and is a longitudinal cross-sectional view (lower portion) of a portion indicated by a one-dot chain line portion in the upper part.

FIG. 2 is a plan view of a high-frequency signal transmission line 102 according to a second example embodiment of the present invention.

FIG. 3 is a longitudinal cross-sectional view (upper portion) taken along a one-dot chain line A-A in FIG. 2, and is a longitudinal cross-sectional view (lower portion) taken along a one-dot chain line B-B in FIG. 2.

FIG. 4 is a plan view of each layer in the middle of the manufacturing process of the high-frequency signal transmission line 102.

FIG. 5 is a cross-sectional view of a high-frequency signal transmission line 103 according to a third example embodiment of the present invention.

FIG. 6 is a cross-sectional view of a high-frequency signal transmission line 104 according to a fourth example embodiment of the present invention.

FIG. 7 is a cross-sectional view of a high-frequency signal transmission line 105 according to a fifth example embodiment of the present invention.

FIG. 8 is a cross-sectional view of a high-frequency signal transmission line 106 according to a sixth example embodiment of the present invention.

FIG. 9 is a cross-sectional view of a high-frequency signal transmission line 107 according to a seventh example embodiment of the present invention.

FIG. 10 is a plan view (upper portion) of a high-frequency signal transmission line 108 according to an eighth example embodiment of the present invention, and is a longitudinal cross-sectional view (lower portion) of a portion indicated by a one-dot chain line in the upper part.

FIG. 11 is a plan view (upper portion) of a high-frequency signal transmission line 109 according to a ninth example embodiment of the present invention, and is a longitudinal cross-sectional view (lower portion) of a portion indicated by a one-dot chain line in the upper part.

FIG. 12 is a plan view of high-frequency signal transmission lines 110A and 110B according to a tenth example embodiment of the present invention.

FIG. 13 is a plan view of first resin layers 11 of four types of high-frequency signal transmission lines according to an eleventh example embodiment of the present invention.

FIG. 14 is a plan view of first resin layers 11 of two types of high-frequency signal transmission lines according to the eleventh example embodiment of the present invention.

FIG. 15 is a cross-sectional view (upper portion) of a high-frequency signal transmission line 112 according to a twelfth example embodiment of the present invention. FIG. 15 is a cross-sectional view (lower portion) of the high-frequency signal transmission line 112 illustrating a state of the electric field distribution by the lines of electric force.

FIG. 16 is a longitudinal cross-sectional view of a high-frequency signal transmission line 113A according to a thirteenth example embodiment of the present invention.

FIG. 17 is a longitudinal cross-sectional view of a high-frequency signal transmission line 113B according to the thirteenth example embodiment of the present invention.

FIG. 18 is a longitudinal cross-sectional view of a high-frequency signal transmission line 114 according to a fourteenth example embodiment of the present invention.

### DETAILED DESCRIPTION OF THE EXAMPLE EMBODIMENTS

Hereinafter, a plurality of example embodiments of the present invention will be shown with some specific examples with reference to the drawings. In each figure, the same elements, components, portions, features, etc., are designated by the same reference signs. In consideration of the description of the main points or ease of understanding, the example embodiments are divided into a plurality of example embodiments for convenience of description, but partial replacement or combination of configurations shown in different example embodiments is possible. In second and subsequent example embodiments, description of matters common to a first example embodiment will be omitted, and only different points will be described. In particular, similar functions and effects obtained by the same configuration will not be sequentially described for each example embodiment.

In the first example embodiment, an example of a microstrip-line-type high-frequency signal transmission line will be described.

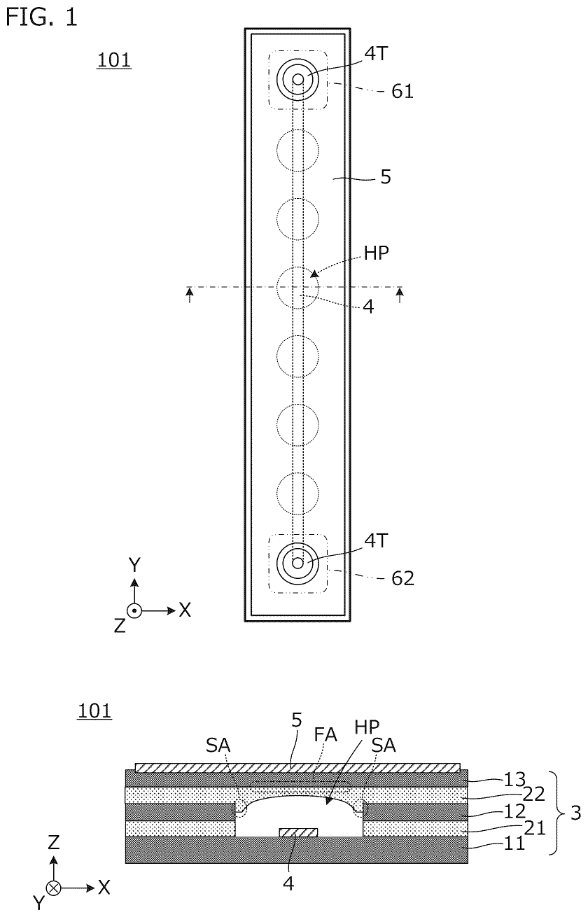

An upper portion of FIG. 1 is a plan view of a high-frequency signal transmission line 101 according to the first example embodiment, and a lower portion of FIG. 1 is a longitudinal cross-sectional view of a portion indicated by a one-dot chain line in the upper portion of FIG. 1. Although a single high-frequency signal transmission line 101 is illustrated in FIG. 1, a large number of high-frequency signal transmission lines continuous in the plane direction are manufactured until the final process at the time of manufacturing, and are separated into the high-frequency signal transmission lines in the final process. This also applies to each example embodiment described below.

The high-frequency signal transmission line 101 includes a resin stacked portion 3, a signal conductor pattern 4, and a ground conductor layer 5.

The resin stacked portion 3 is a portion where first resin layers 11, 12, and 13 and second resin layers 21 and 22 are stacked. The signal conductor pattern 4 is located on the upper surface of the first resin layer 11. The ground conductor layer 5 is stacked on the upper surface of the first resin layer 13. That is, the signal conductor pattern 4 and the ground conductor layer 5 face each other with a portion of the resin stacked portion 3 interposed therebetween.

A circular opening is located in the first resin layer 12 and the second resin layer 21. When expressed by the shape in the drawing, this opening is circular as viewed in the stacking direction of the first resin layers 11, 12, and 13 and the second resin layers 21 and 22.

As described above, since the opening is located in the first resin layer 12 at the position along the signal conductor pattern 4 in the resin stacked portion 3, a hollow portion HP is provided in the resin stacked portion 3 at the opening. In particular, in the present example embodiment, the hollow portion HP in which the first resin layer 12 and the second resin layer 22 are not in contact with the signal conductor pattern 4 is provided. The hollow portion HP overlaps with the signal conductor pattern 4 when viewed in a direction of stacking, and is located between the signal conductor pattern 4 and the ground conductor layer 5. The maximum width of the hollow portion HP, that is, the diameter of the opening portion of the first resin layer 12, is larger than the width of the signal conductor pattern 4.

Note that the present invention is not limited to the present example embodiment, and in the present invention, the “stacking direction” does not mean the direction of the stacking order of the layers at the time of manufacturing, but means the direction of stacking of the layers in the illustrated state.

As illustrated in the upper portion of FIG. 1, the high-frequency signal transmission line 101 has six hollow portions HP, for example. That is, the signal conductor pattern 4 passes through the hollow portion HP at these six locations. The high-frequency signal transmission line 101 acts as a microstrip line including the signal conductor pattern 4, the ground conductor layer 5, a portion of the resin stacked portion 3, and the hollow portion HP.

When the interval between the adjacent hollow portions HP is less than about 1/4 wavelength of the transmission signal, the periodic change in the characteristic impedance accompanying the change in the relative permittivity around the signal conductor pattern 4 does not cause a problem.

As illustrated in the upper portion of FIG. 1, a signal conductor pattern terminal 4T separated from the ground conductor layer 5 is located on the upper surface of the resin stacked portion 3. An end of the signal conductor pattern 4 is connected to the signal conductor pattern terminal 4T via an interlayer connection conductor. A coaxial connector 61 is mounted on the upper signal conductor pattern terminal 4T, and a coaxial connector 62 is mounted on the lower signal conductor pattern terminal 4T. As described above, the high-frequency signal transmission line 101 is used as a transmission line having coaxial connectors at both ends. Regarding the coaxial connectors 61 and 62 in FIG. 1, mounting positions thereof are illustrated.

Each of the signal conductor pattern 4 and the ground conductor layer 5 is, for example, a copper foil. The material of the first resin layers 11, 12, and 13 is, for example, polyimide, liquid crystal polymer, epoxy resin, or the like. The material of the second resin layers 21 and 22 includes, for example, thermoplastic polyimide, fluorine-based resin, polyolefin-based resin, or the like. The polyolefin-based resin includes, for example, styrene, polyethylene, polypropylene, or the like. The second resin layers 21 and 22 act as adhesive layers to bond adjacent first resin layers among the first resin layers 11, 12, and 13.

The flexibility of the second resin layers 21 and 22 at normal temperature is larger than the flexibility of the first resin layers 11, 12, and 13 at normal temperature. Here, the normal temperature is, for example, about 25 °C or room temperature.

For example, the Young's modulus of the second resin layers 21 and 22 is about 1 MPa or less, and the Young's modulus of the first resin layers 11, 12, and 13 is about 2 MPa or more.

In addition, it is preferable that the second resin layers 21 and 22 have high fluidity at the processing stage. The adhesive may flow, adhere a portion of the end surface (inner end surface) in the opening, and then cure. As a material of the second resin layers 21 and 22, for example, a prepreg material used for interlayer adhesion can be considered.

A relative permittivity of the second resin layer is lower than a relative permittivity of the first resin layer. For example, the relative permittivity of the second resin layers 21 and 22 is about 2.2 to about 2.8, and the relative permittivity of the first resin layers 11, 12, and 13 is about 2.8 to about 4.0.

A dielectric loss tangent of the second resin layer is lower than a dielectric loss tangent of the first resin layer. For example, the dielectric loss tangent of the second resin layers 21 and 22 is about 0.0005 to about 0.003, and the dielectric loss tangent of the first resin layers 11, 12, and 13 is about 0.002 to about 0.01.

Any one of the magnitude relationship of the relative permittivity and the magnitude relationship of the dielectric loss tangent may satisfy the above relationship.

In the second resin layer 22 in contact with the first resin layer 12 in which the opening is formed, the maximum thickness and the minimum thickness are different in the opening located in the first resin layer 12, whereby the second resin layer 22 adheres to a portion of the end surface (inner end surface) in the opening of the first resin layer 12 in which the opening is located. That is, the second resin layer 22 is adhered to a portion of the end surface (inner surface) of the opening of the first resin layer 12 to form an adhesive portion SA. A portion having the minimum thickness in the second resin layer 22, when viewed in the stacking direction, is located in the center of the opening portion of the first resin layer 12 in a width direction (an X-axis direction) of the signal conductor pattern 4. A portion having the maximum thickness in the second resin layer 22, when viewed in the stacking direction, is located at the end of the opening portion of the first resin layer 12 in the width direction of the signal conductor pattern 4, and is equivalent to an adhesive portion SA.

In the present example embodiment, the portion of the second resin layer defining a portion of the hollow portion (a portion of the second resin layer 22) is a curved surface in which the vicinity of the center of the hollow portion HP expands outward of the hollow portion HP as compared with the periphery of the hollow portion HP. This curved surface is, for example, an ellipsoid curved surface expressed by x²/a²+y²/b²+z²/c²=1 when a, b, and c are half lengths of diameters in the X-axis, Y-axis, and Z-axis directions, respectively. In the cross section illustrated in the lower portion of FIG. 1, the curved surface includes an elliptical arc. Here, if a=b=c, the cross section of the curved surface is a circular arc. In other words, a portion of the second resin layer 22 defining the hollow portion HP with the first resin layers 11 and 12 and the second resin layer 21 and located in the stacking direction to the opening portion of the first resin layer 12 has an arch shape.

The second resin layer 22 is a curved surface in which the vicinity of the center expands outward of the hollow portion as compared with the periphery of the hollow portion, but the first resin layer 13 and the second resin layer 22 are adhered to each other on the entire surface. That is, the first resin layer 13 is not exposed to the inside of the hollow portion HP.

A portion FA illustrated in the lower portion of FIG. 1 indicates an adhesive portion adhered to the first resin layer 13 while the film thickness of the second resin layer 22 is thinner than that of the adhesive portion SA.

According to the present example embodiment, the following functions and effects listed below are exhibited.

(a) Since the second resin layer 22 as an adhesive layer also adheres to the end surface (inner surface) at the opening of the first resin layer 12, the adhesion strength between the second resin layer 22 and the first resin layer 12 is high. Therefore, the strength of the hollow portion HP is high, stress applied to the high-frequency signal transmission line 101 from the outside is relaxed, and damage such as peeling between the layers is prevented.

(b) Since the portion of the hollow portion HP in the resin stacked portion 3 is a curved surface in which the vicinity of the center of the hollow portion HP extends outward from the periphery of the hollow portion HP, the air layer in the vicinity of the signal conductor pattern 4 is thicker. Therefore, both the dielectric loss tangent and the dielectric constant of the dielectric between the signal conductor pattern 4 and the ground conductor layer 5 are small, and the dielectric loss of the high-frequency signal transmission line is reduced.

(c) The portion of the hollow portion in the second resin layer having relatively high flexibility rather than the first resin layer having relatively low flexibility is a curved surface in which the vicinity of the center of the portion expands outward from the periphery of the hollow portion. Therefore, stress applied to the high-frequency signal transmission line 101 from the outside is effectively relaxed in the second resin layer, and a decrease in strength due to the presence of the hollow portion HP is reduced or prevented.

(d) When the relative permittivity of the second resin layer on the side close to the signal conductor pattern 4 is lower than the relative permittivity of the first resin layer, the effect of reducing the dielectric loss is excellent. Similarly, when the dielectric loss tangent of the second resin layer on the side close to the signal conductor pattern 4 is lower than the dielectric loss tangent of the first resin layer, the effect of reducing the dielectric loss is excellent.

(e) Since the second resin layer 22 includes a curved surface in which the vicinity of the center expands outward of the hollow portion as compared with the periphery of the hollow portion HP, and the first resin layer 13 and the second resin layer 22 are adhered to each other on the entire surface, the bonding strength between the first resin layer 13 and the second resin layer 22 is high. Therefore, the strength of the hollow portion HP is high, stress applied to the high-frequency signal transmission line 101 from the outside is relaxed, and damage is prevented.

(f) Although FIG. 1 illustrates an example embodiment in which the signal conductor pattern 4 is exposed in the hollow portion HP, an example embodiment in which the signal conductor pattern 4 is located on the lower surface of the first resin layer 11 (surface opposite to the surface on which the hollow portion HP is located) is also conceivable. In this case, it is easy to secure the distance between the ground conductor layer 5 and the signal conductor pattern 4. Therefore, the line width of the signal conductor pattern can be increased in order to obtain a predetermined characteristic impedance, and accordingly, the transmission loss can be reduced.

In the second example embodiment, an example of a strip-line-type high-frequency signal transmission line in which a hollow portion HP exists around a signal conductor pattern 4 will be described.

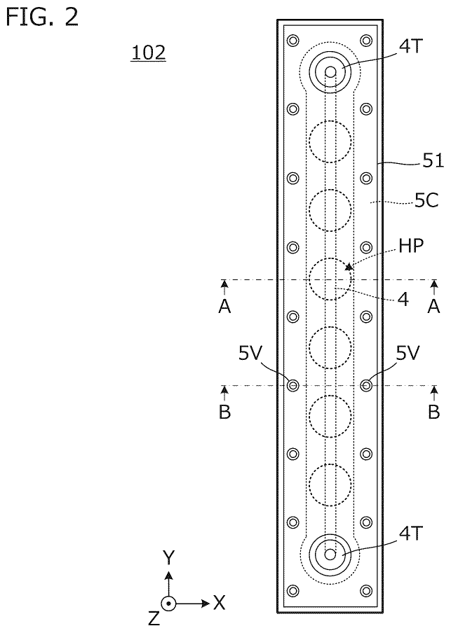

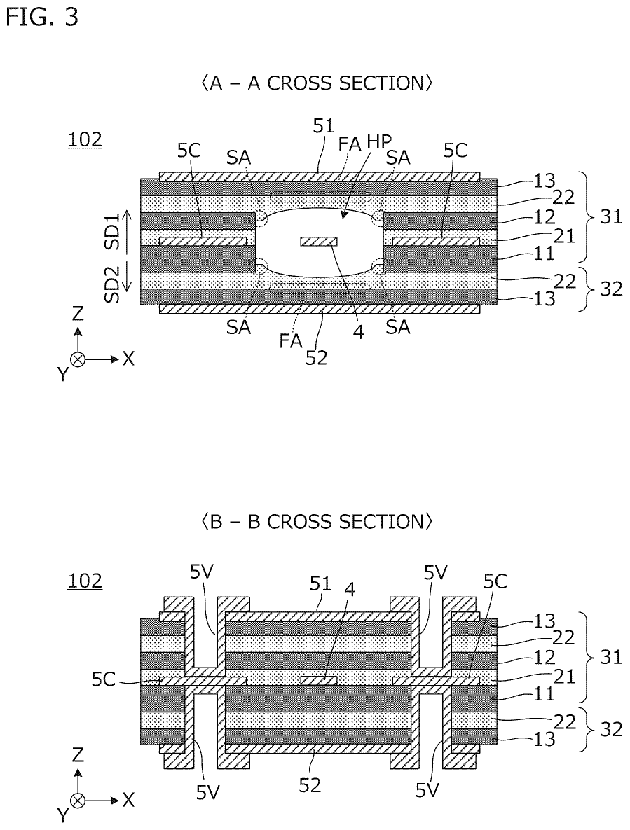

FIG. 2 is a plan view of a high-frequency signal transmission line 102 according to the second example embodiment. The upper portion of FIG. 3 is a longitudinal cross-sectional view taken along a one-dot chain line A-A in FIG. 2, and the lower portion of FIG. 3 is a longitudinal cross-sectional view taken along a one-dot chain line B-B in FIG. 2.

The high-frequency signal transmission line 102 includes an upper resin stacked portion 31, a lower resin stacked portion 32, a signal conductor pattern 4, a first ground conductor layer 51, a second ground conductor layer 52, a ground conductor pattern 5C, and an interlayer connection conductor 5V.

The upper resin stacked portion 31 is a portion where the upper first resin layers 11, 12, and 13 and the upper second resin layers 21 and 22 are stacked. The lower resin stacked portion 32 is a portion where the lower first resin layer 13 and the lower second resin layer 22 are stacked. That is, the resin stacked portion includes the upper resin stacked portion 31 stacked in a first stacking direction SD1 in the direction of stacking of the first resin layer and the second resin layer, and the lower resin stacked portion 32 configured in a second stacking direction SD2 opposite to the first stacking direction SD1.

The signal conductor pattern 4 and the ground conductor pattern 5C are located on the upper surface of the first resin layer 11. A first ground conductor layer 51 is stacked on the upper surface of the upper first resin layer 13. A second ground conductor layer 52 is stacked on the lower surface of the lower first resin layer 13. That is, the signal conductor pattern 4 faces the first ground conductor layer 51 and the second ground conductor layer 52 with the upper resin stacked portion 31 and the lower resin stacked portion 32 interposed therebetween.

As illustrated in the lower portion of FIG. 3, an interlayer connection conductor 5V is located in the upper resin stacked portion 31. These interlayer connection conductors 5V electrically connect the first ground conductor layer 51 and the ground conductor pattern 5C. An interlayer connection conductor 5V is located in the lower resin stacked portion 32. These interlayer connection conductors 5V electrically connect the second ground conductor layer 52 and the ground conductor pattern 5C.

Circular openings are located in the first resin layers 11 and 12 and the second resin layer 21. When expressed by the shape in the drawing, this opening is circular as viewed in the stacking direction of the first resin layers 11, 12, and 13 and the second resin layers 21 and 22.

As described above, since the opening is located in the first resin layer 12 at the position along the signal conductor pattern 4 in the upper resin stacked portion 31, the hollow portion HP is provided around the signal conductor pattern 4 by the opening. In particular, in the present example embodiment, the hollow portion HP in which the first resin layers 11 and 12 and the second resin layers 21 and 22 are not in contact with the signal conductor pattern 4 is located.

As illustrated in FIG. 2, the high-frequency signal transmission line 102 includes six hollow portions HP, for example. That is, the signal conductor pattern 4 passes through the hollow portion HP at these six locations. The high-frequency signal transmission line 102 defines and functions as a strip line including the signal conductor pattern 4, the first ground conductor layer 51, the second ground conductor layer 52, the upper resin stacked portion 31, the lower resin stacked portion 32, and the hollow portion HP.

Similarly to the example described in the first example embodiment, when the interval between the hollow portions HP is less than about ¼ wavelength of the transmission signal, the periodic change in the characteristic impedance accompanying the change in the relative permittivity around the signal conductor pattern 4 does not cause a problem.

Each of the signal conductor pattern 4, the first ground conductor layer 51, and the second ground conductor layer 52 includes, for example, a copper foil. The material of the first resin layers 11, 12, and 13 is, for example, polyimide, liquid crystal polymer, epoxy resin, or the like. The material of the second resin layers 21 and 22 includes, for example, thermoplastic polyimide, fluorine-based resin, polyolefin-based resin, or the like. The polyolefin-based resin includes, for example, styrene, polyethylene, polypropylene, or the like. The second resin layers 21 and 22 act as adhesive layers to bond adjacent first resin layers among the first resin layers 11, 12, and 13.

The relationship in flexibility between the second resin layers 21 and 22 and the first resin layers 11, 12, and 13, the relationship in relative permittivity between the second resin layers 21 and 22 and the first resin layers 11, 12, and 13, and the relationship in dielectric loss tangent between the second resin layers 21 and 22 and the first resin layers 11, 12, and 13 are the same as those in the example described in the first example embodiment.

In the upper portion of FIG. 3, a portion indicated by a broken line in the upper portion of the drawing is an adhesive portion SA in which the upper second resin layer 22 is adhered to a portion of the end surface (inner surface) in the opening of the first resin layer 12.

In the upper portion of FIG. 3, a portion FA indicated by a broken line in the upper portion of the drawing indicates an adhesive portion adhered to the upper first resin layer 13 while the film thickness of the upper second resin layer 22 is thinner than the original thickness.

Further, a portion indicated by a lower broken line in the drawing is an adhesive portion SA in which the lower second resin layer 22 is adhered to a portion of an end surface (inner surface) of the opening of the first resin layer 11.

In the upper portion of FIG. 3, a portion FA indicated by a broken line in the lower portion of the drawing indicates an adhesive portion adhered to the lower first resin layer 13 while the film thickness of the lower second resin layer 22 is thinner than the original thickness.

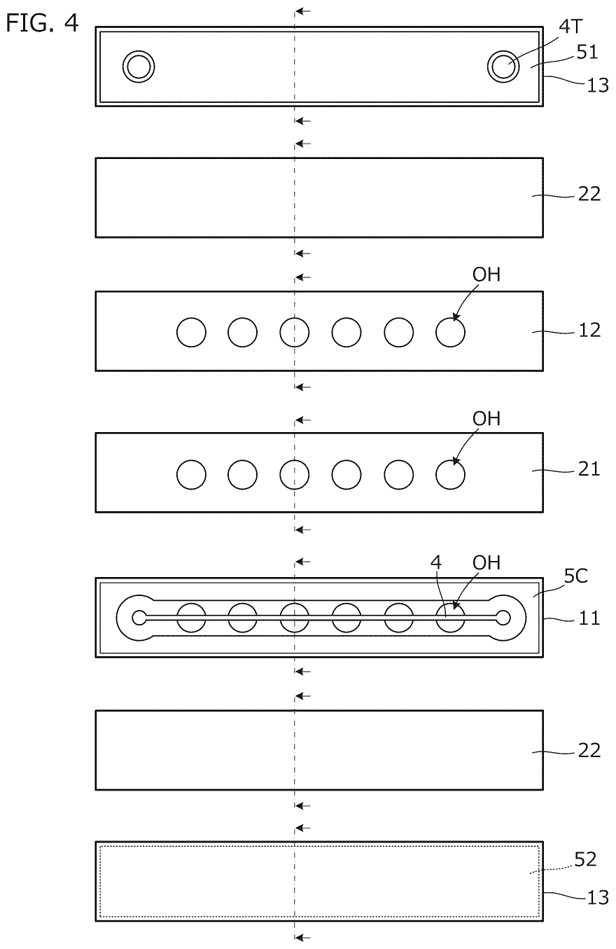

FIG. 4 is a plan view of each layer in the middle of the manufacturing process of the high-frequency signal transmission line 102. As described above, the high-frequency signal transmission line 102 includes the first resin layer 13, the second resin layer 22, the first resin layer 12, the second resin layer 21, the first resin layer 11, the second resin layer 22, and the first resin layer 13 when layers of the high-frequency signal transmission line are listed in order from the top. Circular openings OH are located in the first resin layers 11 and 12 and the second resin layer 21. When these resin layers are stacked and pressurized and heated, as illustrated in the upper portion of FIG. 3, due to melting of the upper second resin layer 22, the upper second resin layer extends to the end surface (inner surface) in the opening of the first resin layer 12. Similarly, due to melting of the lower second resin layer 22, the lower second resin layer extends to the end surface (inner surface) of the opening of the first resin layer 11. Further, the hollow portion HP due to the overlapping of the openings OH expands by heating. That is, the film thickness of the upper second resin layer 22 is thinner than the original thickness of the upper second resin layer 22, and the film thickness of the lower second resin layer 22 is thinner than the original thickness of the lower second resin layer 22, so that the hollow portion HP expands in the stacking direction.

The interlayer connection conductor 5V illustrated in FIG. 3 is formed by forming a hole for exposing the ground conductor pattern 5C from the outer surface of the stacked body obtained by stacking the resin layers by laser processing, and forming a copper plated film in the hole.

According to the present example embodiment, the same functions and effects as those described in the first example embodiment are obtained. As other effects, in the present example embodiment, the following functions and effects are obtained.

(a) Since the hollow portion HP extends also below the signal conductor pattern 4, the dielectric loss of the high-frequency signal transmission line is more effectively reduced.

(b) The interlayer connection conductors 5V are arranged on both sides of the arrangement line of the hollow portions HP when viewed in the stacking direction of the respective resins, and the intermediate position of the arrangement pitch of the hollow portions HP and the arrangement position of the interlayer connection conductors 5V coincide with each other, so that the strength of the stacked body by stacking the respective resin layers is uniformly increased by the interlayer connection conductors 5V.

(c) Since the second resin layers 21 and 22 are more flexible than the first resin layers 11, 12, and 13, the second resin layers 21 and 22 can absorb the step of the ground conductor pattern 5C and wrap around the inner surface of the hollow portion HP in a stable shape. Incidentally, when the flexibility of each resin layer is equal (when the first resin layers 11, 12, and 13 and the second resin layers 21 and 22 are both flexible), it is difficult to stably maintain the shape of the hollow portion HP.

In the third example embodiment, a high-frequency signal transmission line in which the shape of the hollow portion HP is different from that of the examples described in the first and second example embodiments will be described.

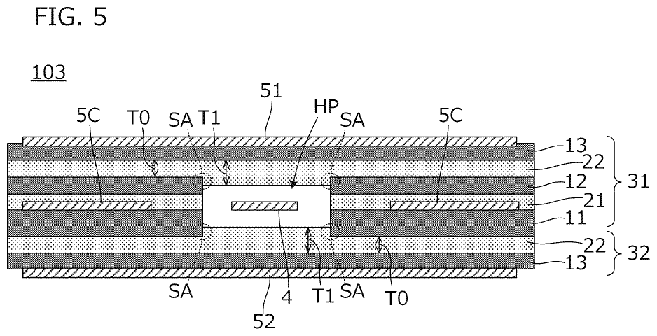

FIG. 5 is a cross-sectional view of a high-frequency signal transmission line 103 according to the third example embodiment.

The high-frequency signal transmission line 103 includes an upper resin stacked portion 31, a lower resin stacked portion 32, a signal conductor pattern 4, a first ground conductor layer 51, a second ground conductor layer 52, a ground conductor pattern 5C, and an interlayer connection conductor (for example, an interlayer connection conductor 5V illustrated in FIG. 3).

The upper resin stacked portion 31 is a portion where the upper first resin layers 11, 12, and 13 and the upper second resin layers 21 and 22 are stacked. The lower resin stacked portion 32 is a portion where the lower first resin layer 13 and the lower second resin layer 22 are stacked.

The signal conductor pattern 4 and the ground conductor pattern 5C are located on the upper surface of the first resin layer 11. A first ground conductor layer 51 is stacked on the upper surface of the upper first resin layer 13. A second ground conductor layer 52 is stacked on the lower surface of the lower first resin layer 13. That is, the signal conductor pattern 4 faces the first ground conductor layer 51 and the second ground conductor layer 52 with the upper resin stacked portion 31 and the lower resin stacked portion 32 interposed therebetween.

Circular openings are located in the first resin layers 11 and 12 and the second resin layer 21. When expressed by the shape in the drawing, this opening is circular as viewed in the stacking direction of the first resin layers 11, 12, and 13 and the second resin layers 21 and 22.

Since the opening is located in the first resin layers 11 and 12 at the position along the signal conductor pattern 4 in the upper resin stacked portion 31, the hollow portion HP is provided around the signal conductor pattern 4 by the opening.

The upper second resin layer 22 in contact with the first resin layer 12 having the opening protrudes into the opening of the first resin layer 12, and in the region of the opening of the first resin layer 12, the thickness T1 of the upper second resin layer 22 is larger than the thickness T0 of the other region. Similarly, the lower second resin layer 22 in contact with the first resin layer 11 having the opening protrudes into the opening of the first resin layer 11, and in the region of the opening of the first resin layer 11, the thickness T1 of the lower second resin layer 22 is larger than the thickness T0 of the other region.

With the above-described structure, the upper second resin layer 22 adheres to a portion of the end surface (inner end surface) in the opening of the first resin layer 12 in which the opening is formed. Similarly, the lower second resin layer 22 adheres to a portion of the end surface (inner end surface) of the opening of the first resin layer 11 in which the opening is located.

According to the present example embodiment, as in the case of the high-frequency signal transmission line described in the second example embodiment, the adhesion strength between the upper second resin layer 22 and the first resin layer 12 and the adhesion strength between the lower second resin layer 22 and the first resin layer 11 are high. Therefore, the strength of the hollow portion HP is high, stress applied to the high-frequency signal transmission line 101 from the outside is relaxed, and damage is prevented. In addition, since the second resin layers 22 on the upper and lower sides of the hollow portion HP are thick and flat, the strength of the hollow portion HP can be easily increased. The cross-sectional shape of the hollow portion HP can be changed by the flexibility of the second resin layer 22 or the like.

In the fourth example embodiment, a high-frequency signal transmission line in which a hollow portion is relatively expanded as compared with the example embodiments described above will be exemplified.

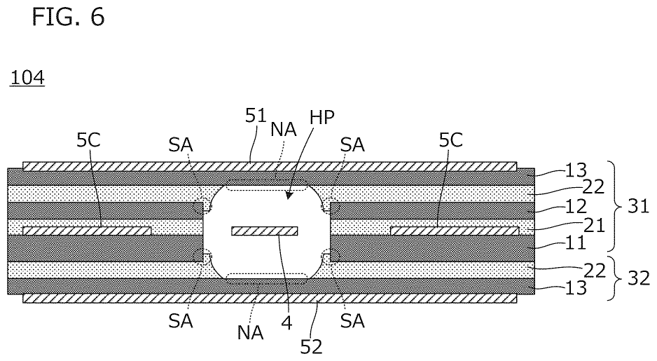

FIG. 6 is a cross-sectional view of a high-frequency signal transmission line 104 according to the fourth example embodiment.

The high-frequency signal transmission line 104 includes an upper resin stacked portion 31, a lower resin stacked portion 32, a signal conductor pattern 4, a first ground conductor layer 51, a second ground conductor layer 52, and a ground conductor pattern 5C. As described in the second example embodiment, the ground conductor pattern 5C is a ground conductor pattern of an intermediate layer electrically connected to the first ground conductor layer 51 and the second ground conductor layer 52 via the interlayer connection conductor.

Differences from the high-frequency signal transmission line 102 illustrated in the upper portion of FIG. 3 are that a non-adhesive portion NA exists between the upper second resin layer 22 and the upper first resin layer 13, and that the non-adhesive portion NA exists between the lower second resin layer 22 and the lower first resin layer 13.

According to the present example embodiment, as compared with the high-frequency signal transmission line described in the second example embodiment, the air layers above and below the signal conductor pattern 4 can be thickened, and the dielectric loss can be more effectively reduced.

In the example illustrated in FIG. 6, the non-adhesive portion NA is located on both the upper and lower sides of the signal conductor pattern 4, but the non-adhesive portion NA may be located on only one of the upper and lower sides.

The high-frequency signal transmission line 104 of the present example embodiment is manufactured by the following non-limiting method. In one method, when the upper second resin layer 22 is applied to the upper first resin layer 13, the second resin layer is applied except for a position facing the opening of the first resin layer 12. Similarly, when the lower second resin layer 22 is applied to the lower first resin layer 13, the second resin layer is applied except for a position facing the opening of the first resin layer 11. In another method, after the upper second resin layer 22 is applied to the entire surface of the upper first resin layer 13, the vicinity of the position facing the opening of the first resin layer 12 is partially removed. Similarly, after the lower second resin layer 22 is applied to the entire surface of the lower first resin layer 13, the vicinity of the position facing the opening of the first resin layer 11 is partially removed.

According to the present example embodiment, the height of the hollow portion HP can be easily increased.

In the fifth example embodiment, a high-frequency signal transmission line in which different second resin layers are connected to each other around the hollow portion will be exemplified.

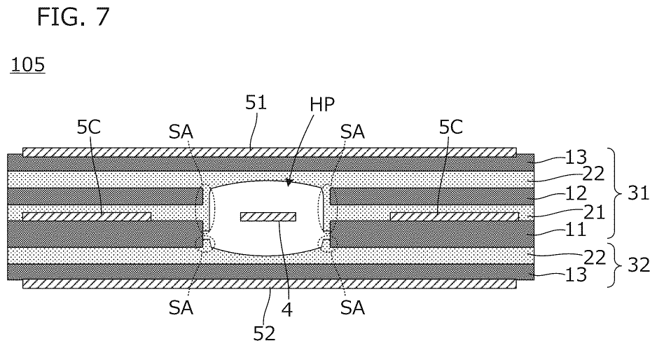

FIG. 7 is a cross-sectional view of a high-frequency signal transmission line 105 according to the fifth example embodiment.

The high-frequency signal transmission line 105 includes an upper resin stacked portion 31, a lower resin stacked portion 32, a signal conductor pattern 4, a first ground conductor layer 51, a second ground conductor layer 52, and a ground conductor pattern 5C. As described in the second example embodiment, the ground conductor pattern 5C is a ground conductor pattern of an intermediate layer electrically connected to the first ground conductor layer 51 and the second ground conductor layer 52 via the interlayer connection conductor.

The following two points are different from the high-frequency signal transmission line 102 illustrated in the upper portion of FIG. 3.

(1) The upper second resin layer 22 and the second resin layer 21 are connected along the hollow portion HP.

(2) The second resin layer 21 and the upper second resin layer 22 are adhered to a portion of the end surface (inner surface) in the opening of the first resin layer 11.

According to the present example embodiment, since the second resin layer 21 and the upper second resin layer 22 as adhesive layers adhere to the entire end surface (inner surface) of the opening of the first resin layer 12 in the thickness direction, the adhesion strength between the second resin layers 21 and 22 and the first resin layer 12 is high. Therefore, the strength of the hollow portion HP is more effectively enhanced.

In the sixth example embodiment, an example of a suspended line type of the high-frequency signal transmission line in which the hollow portion HP exists above the signal conductor pattern 4 and another hollow portion HP exists below the first resin layer 11 on which the signal conductor pattern is located will be described.

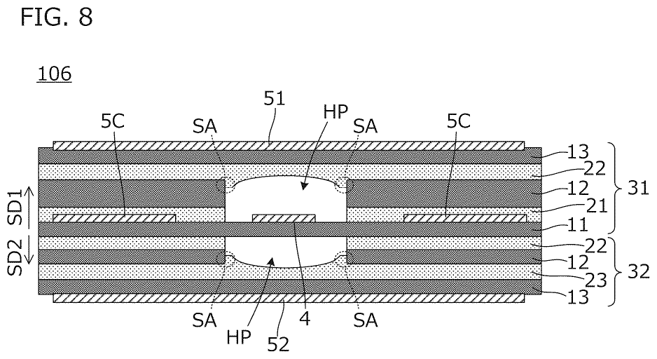

FIG. 8 is a cross-sectional view of a high-frequency signal transmission line 106 according to the sixth example embodiment.

The high-frequency signal transmission line 106 includes an upper resin stacked portion 31, a lower resin stacked portion 32, a signal conductor pattern 4, a first ground conductor layer 51, a second ground conductor layer 52, and a ground conductor pattern 5C.

The upper resin stacked portion 31 is a portion where the upper first resin layers 11, 12, and 13 and the upper second resin layers 21 and 22 are stacked. The lower resin stacked portion 32 is a portion where the lower first resin layers 12 and 13 and the lower second resin layers 22 and 23 are stacked. That is, the resin stacked portion includes the upper resin stacked portion 31 stacked in a first stacking direction SD1 in the direction of stacking of the first resin layer and the second resin layer, and the lower resin stacked portion 32 configured in a second stacking direction SD2 opposite to the first stacking direction SD1.

The signal conductor pattern 4 and the ground conductor pattern 5C are located on the upper surface of the first resin layer 11. A first ground conductor layer 51 is stacked on the upper surface of the upper first resin layer 13. A second ground conductor layer 52 is stacked on the lower surface of the lower first resin layer 13.

A circular opening is located in the upper first resin layer 12 and the second resin layer 21. In addition, circular openings are located in the lower first resin layer 12 and the lower second resin layer 22.

Other structures are similar to those of the high-frequency signal transmission line described in the second example embodiment.

According to the present example embodiment, since the first resin layer 11 continuously supporting the signal conductor pattern 4 is present, the strength of the signal conductor pattern 4 can be easily increased.

In the seventh example embodiment, an example of a high-frequency signal transmission line in which the shape of the hollow portion HP above and below the signal conductor pattern 4 is different from the example described in the sixth example embodiment will be described.

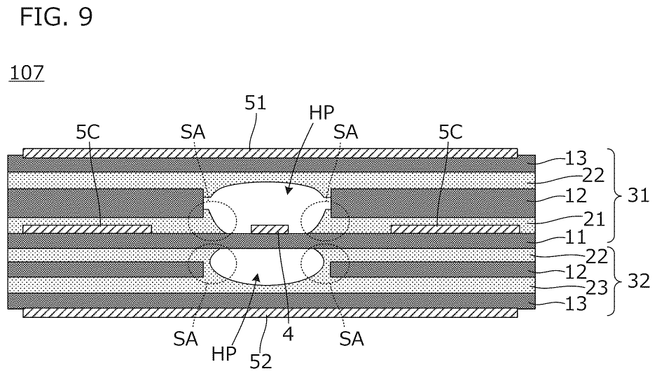

FIG. 9 is a cross-sectional view of a high-frequency signal transmission line 107 according to the seventh example embodiment.

The high-frequency signal transmission line 107 includes an upper resin stacked portion 31, a lower resin stacked portion 32, a signal conductor pattern 4, a first ground conductor layer 51, a second ground conductor layer 52, and a ground conductor pattern 5C.

Other structures are similar to those of the high-frequency signal transmission line described in the sixth example embodiment.

Differences from the high-frequency signal transmission line 106 illustrated in FIG. 8 are as follows.

(1) The second resin layer 21, which is an upper adhesive layer of the first resin layer 11 on which the signal conductor pattern 4 is located, also adheres to a portion of the end surface (inner surface) in the opening of the upper first resin layer 12. An upper adhesive portion SA in FIG. 9 represents that portion.

(2) The second resin layers 22 and 23, which are lower adhesive layers of the first resin layer 11 on which the signal conductor pattern 4 is formed, also adhere to a portion of the end surface (inner surface) in the opening of the lower first resin layer 12. A lower adhesive portion SA in FIG. 9 represents that portion.

According to the present example embodiment, since the side surface of the other first resin layer adjacent to the first resin layer on which the signal conductor pattern 4 is located is also adhered by the second resin layer, the strength of the hollow portion HP is high, the stress applied to the high-frequency signal transmission line 107 from the outside is relaxed, and damage is prevented.

In the eighth example embodiment, a high-frequency signal transmission line in which a hollow portion is located in an extending direction of the signal conductor pattern 4 will be exemplified.

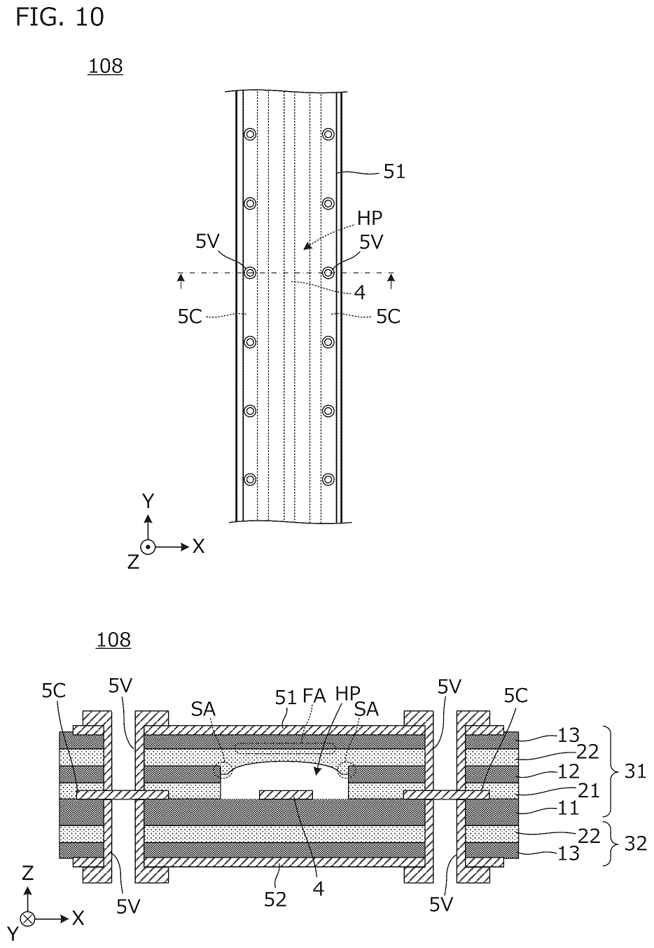

The upper portion of FIG. 10 is a plan view of a high-frequency signal transmission line 108 according to the eighth example embodiment, and the lower portion of FIG. 10 is a longitudinal cross-sectional view of a portion indicated by a one-dot chain line in the upper portion of FIG. 10.

The high-frequency signal transmission line 108 includes an upper resin stacked portion 31, a lower resin stacked portion 32, a signal conductor pattern 4, a first ground conductor layer 51, a second ground conductor layer 52, a ground conductor pattern 5C, and an interlayer connection conductor 5V.

The upper resin stacked portion 31 is a portion where the upper first resin layers 11, 12, and 13 and the upper second resin layers 21 and 22 are stacked. The lower resin stacked portion 32 is a portion where the lower first resin layer 13 and the lower second resin layer 22 are stacked.

The signal conductor pattern 4 and the ground conductor pattern 5C are located on the upper surface of the first resin layer 11. A first ground conductor layer 51 is stacked on the upper surface of the upper first resin layer 13. A second ground conductor layer 52 is stacked on the lower surface of the lower first resin layer 13. That is, the signal conductor pattern 4 faces the first ground conductor layer 51 and the second ground conductor layer 52 with the upper resin stacked portion 31 and the lower resin stacked portion 32 interposed therebetween.

The interlayer connection conductor 5V is formed in the upper resin stacked portion 31. These interlayer connection conductors 5V electrically connect the first ground conductor layer 51 and the ground conductor pattern 5C. An interlayer connection conductor 5V is formed in the lower resin stacked portion 32. These interlayer connection conductors 5V electrically connect the second ground conductor layer 52 and the ground conductor pattern 5C.

As illustrated in the upper portion of FIG. 10, the high-frequency signal transmission line 108 does not have a plurality of hollow portions HP as illustrated in the upper portion of FIG. 1, for example, but has a continuous hollow portion HP along the extending direction of the signal conductor pattern 4. The high-frequency signal transmission line 108 acts as a strip line including the signal conductor pattern 4, the first ground conductor layer 51, the second ground conductor layer 52, the first resin layer, the second resin layer, and the hollow portion HP.

According to the present example embodiment, since the hollow portion HP is only located in the upper resin layer, the mechanical strength of the signal conductor pattern 4 can be easily maintained high even if stress is applied in the vicinity of the hollow portion HP by an external force on the high-frequency signal transmission line 108. In addition, since the hollow portion HP is not dispersed in the signal propagation direction, the characteristic impedance does not periodically change.

In the ninth example embodiment, a high-frequency signal transmission line in which the positional relationship between the hollow portion and the interlayer connection conductor and the structure of the interlayer connection conductor are different from those of the examples described above will be exemplified.

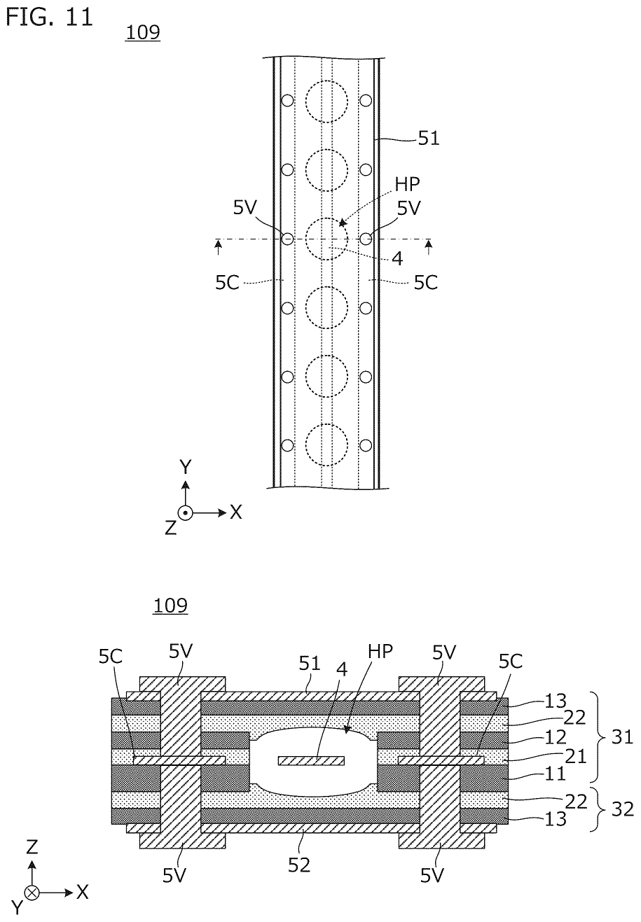

The upper portion of FIG. 11 is a plan view of a high-frequency signal transmission line 109 according to the ninth example embodiment, and the lower portion of FIG. 11 is a longitudinal cross-sectional view of a portion indicated by a one-dot chain line in the upper portion of FIG. 11.

The high-frequency signal transmission line 109 includes an upper resin stacked portion 31, a lower resin stacked portion 32, a signal conductor pattern 4, a first ground conductor layer 51, a second ground conductor layer 52, a ground conductor pattern 5C, and an interlayer connection conductor 5V.

In the high-frequency signal transmission line 102 illustrated in the lower portion of FIG. 3, the interlayer connection conductor 5V is formed by forming a conductor plating film on the inner surface of the opening located in each resin layer between the first ground conductor layer 51 and the ground conductor pattern 5C, and similarly, the interlayer connection conductor 5V is formed by forming a conductor plating film on the inner surface of the opening located in each resin layer between the second ground conductor layer 52 and the ground conductor pattern 5C. However, in the high-frequency signal transmission line 109 illustrated in FIG. 11, the opening located in each resin layer between the first ground conductor layer 51 and the ground conductor pattern 5C is filled with a conductor to provide the interlayer connection conductor 5V, and an opening located in each resin layer between the second ground conductor layer 52 and the ground conductor pattern 5C is filled with a conductor to provide the interlayer connection conductor 5V.

FIG. 2 illustrates an example in which the interlayer connection conductors 5V are arranged on both sides of the arrangement line of the hollow portions HP when viewed in the stacking direction of the respective resins, and the intermediate position of the arrangement pitch of the hollow portions HP and the arrangement position of the interlayer connection conductors 5V coincide with each other. On the other hand, in the high-frequency signal transmission line 109 illustrated in FIG. 11, the interlayer connection conductors 5V are arranged on both sides of the hollow portion HP as viewed in the stacking direction of the respective resins.

According to the present example embodiment, since the interlayer connection conductor 5V exists at a position close to each of the hollow portions HP, the strength of the hollow portion HP is effectively enhanced by the interlayer connection conductor 5V. That is, since the interlayer connection conductors 5V adjacent to the hollow portion HP are located at positions across the hollow portion HP as viewed in the stacking direction of the resin layers, the interlayer connection conductors 5V are located at positions adjacent to the hollow portion HP. As a result, the strength of the hollow portion HP is effectively enhanced by the interlayer connection conductor 5V.

In addition, since the interlayer connection conductor 5V protrudes to the surface layer and straddles the hollow portion, even if there is contact with an object from the outside (even if there is contact with an external object), the object comes into contact with the protruding portion of the interlayer connection conductor 5V and is prevented from hitting the upper and lower sides of the hollow portion HP, so that deformation of the hollow portion HP can be reduced or prevented.

The structure in which the interlayer connection conductors 5V adjacent to the hollow portion HP are located at positions straddling the hollow portion HP is also satisfied in the example illustrated in FIG. 2. That is, in FIG. 2, the interlayer connection conductors 5V adjacent to the hollow portions HP extend across the hollow portions HP along a line inclined at about 45 degrees with respect to the arrangement direction of the hollow portions HP, for example.

In the tenth example embodiment, a high-frequency signal transmission line in which the positional relationship between the hollow portion and the interlayer connection conductor is different from those of the examples described above will be exemplified.

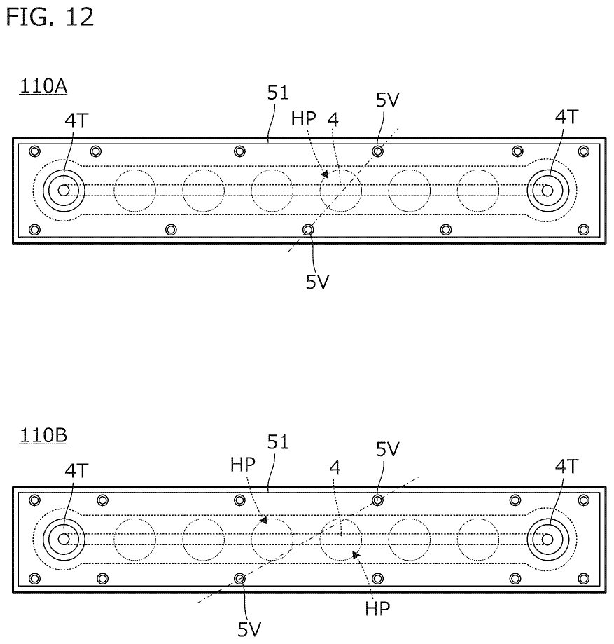

FIG. 12 is a plan view of high-frequency signal transmission lines 110A and 110B according to the tenth example embodiment. Each of the high-frequency signal transmission lines 110A and 110B includes a first ground conductor layer 51, a ground conductor pattern 51C, a signal conductor pattern terminal 4T, a plurality of hollow portions HP, and a plurality of interlayer connection conductors 5V. The inner structure is as shown in the second example embodiment. The second ground conductor layer 52 overlaps with the first ground conductor layer 51 in the plan view.

The high-frequency signal transmission line 110A and the high-frequency signal transmission line 110B are different from each other in the arrangement of the interlayer connection conductors 5V. Both the high-frequency signal transmission lines 110A and 110B include fewer interlayer connection conductors than the examples illustrated in FIGS. 2 and 11.

In the high-frequency signal transmission line 110A, the adjacent interlayer connection conductors 5V pass through (straddle) one hollow portion HP in a positional relationship of sandwiching the hollow portion HP in the plan view.

In the high-frequency signal transmission line 110B, the adjacent interlayer connection conductors 5V pass through (straddle) two hollow portions HP in a positional relationship of sandwiching the hollow portions HP in the plan view.

Even when the number of such interlayer connection conductors 5V is small, if the adjacent interlayer connection conductors 5V pass through (straddle) the hollow portion HP in the positional relationship of sandwiching the hollow portion HP in the plan view, the degree of reinforcement of the hollow portion HP by the interlayer connection conductor 5V is high, stress applied to the high-frequency signal transmission lines 110A and 110B from the outside is relaxed, and damage is prevented.

In the eleventh example embodiment, a high-frequency signal transmission line in which the shape and arrangement pitch of the hollow portion are different from those of the examples described above will be exemplified.

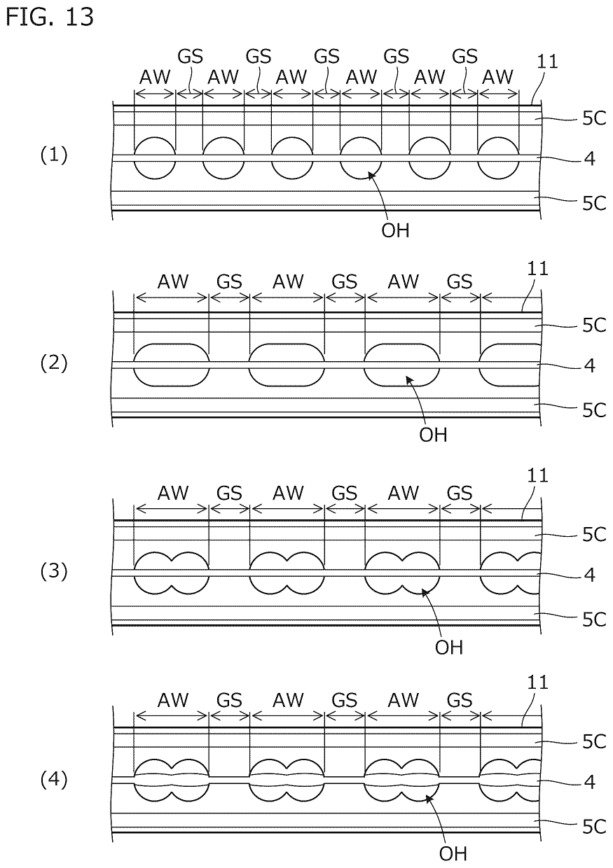

(1) of FIG. 13 is a plan view of the first resin layer 11 of the high-frequency signal transmission line as an example. For example, it is a plan view of the first resin layer 11 of the high-frequency signal transmission line 102 described in the second example embodiment. (2) and (3) of FIG. 13 are plan views of the first resin layer 11 (the first resin layer on which the signal conductor pattern 4 is located) of the high-frequency signal transmission line in which the shape of the hollow portion and the arrangement pitch thereof are different from those in the example of (1). (4) of FIG. 13 is a plan view of the first resin layer 11 of the high-frequency signal transmission line in which the line widths of the signal conductor patterns in the hollow portion and other portions are different.

In the example illustrated in (1) of FIG. 13, a plurality of circular openings OH are located in the first resin layer 11. The width of the opening OH is AW, and the interval between the openings OH is GS. Here, the larger the value of AW/GS, the higher the rate at which the signal conductor pattern 4 passes through the hollow portion, so that the dielectric loss due to the relative permittivity and the dielectric loss tangent of the resin layer is reduced. However, when the value of AW/GS becomes extremely large, the strength of the hollow portion due to the opening OH becomes lower than a specified value, and there is a risk of breakage in the vicinity of the hollow portion.

In particular, when the interval GS becomes small, there is a possibility that the value of AW/GS becomes extremely large due to shortening of the interval GS due to stacking deviation in manufacturing.

In the example illustrated in (2) of FIG. 13, an oval opening OH is located in the first resin layer 11. The width of the opening OH is AW, and the interval between the openings OH is GS. As described above, even if the shape of the opening OH has an aspect ratio, the larger the value of AW/GS, the higher the rate at which the signal conductor pattern 4 passes through the hollow portion, so that the dielectric loss due to the relative permittivity and the dielectric loss tangent of the resin layer is reduced. However, since the long axis of the opening OH is along the extending direction of the signal conductor pattern 4, the lengthening efficiency of the opening OH with respect to the enlargement of the planar area of the opening OH is high. Therefore, even if the value of AW/GS is not extremely increased, the dielectric loss can be effectively reduced, the strength of the hollow portion by the opening OH can be maintained, and the risk of breakage in the vicinity of the hollow portion can be reduced.

When the opening OH is elongated in this manner, the interval GS can be lengthened, so that the strength of the hollow portion can be maintained. For example, in the example illustrated in the upper portion of FIG. 13, if AW=about 4 mm and GS=about 1 mm, in the example illustrated in the middle portion of FIG. 13, by setting AW=about 7 mm and GS=about 1.75 mm, the effect of providing the hollow portion by the opening OH can be equalized.

In the example illustrated in (3) of FIG. 13, an opening OH having a shape in which two circles overlap with each other while being shifted by a certain distance in the extending direction of the signal conductor pattern 4 is located in the first resin layer 11. The width of the opening OH in the extending direction of the signal conductor pattern 4 is AW, and the interval between the openings OH is GS. Even in the case of such an opening OH shape, since the long axis of the opening OH is along the extending direction of the signal conductor pattern 4, the lengthening efficiency of the opening OH with respect to the enlargement of the planar area of the opening OH is high. Moreover, as compared with the example of (2) of FIG. 13, the lengthening efficiency of the opening OH with respect to the enlargement of the planar area of the opening OH is higher. Therefore, the enlargement ratio of the planar area as the value of AW/GS increases is reduced or prevented. As a result, the strength of the hollow portion by the opening OH can be maintained, and the risk of breakage in the vicinity of the hollow portion can be further reduced.

In the example illustrated in (4) of FIG. 13, the line width of the signal conductor pattern 4 is different between a portion stacked on the second resin layer (the second resin layer 21 illustrated in FIG. 3) and a portion not in contact with the second resin layer. The line width of the signal conductor pattern 4 not in contact with the second resin layer is larger than the line width of the signal conductor pattern 4 stacked on the second resin layer. With this structure, the relative permittivity between the signal conductor pattern 4 and the first ground layer (the first ground conductor layer 51 illustrated in FIG. 3) and the relative permittivity between the signal conductor pattern 4 and the second ground conductor layer (the second ground conductor layer 52 illustrated in FIG. 3) can be made uniform, whereby unnecessary reflection due to mismatch of the characteristic impedance in the high-frequency signal can be reduced or prevented.

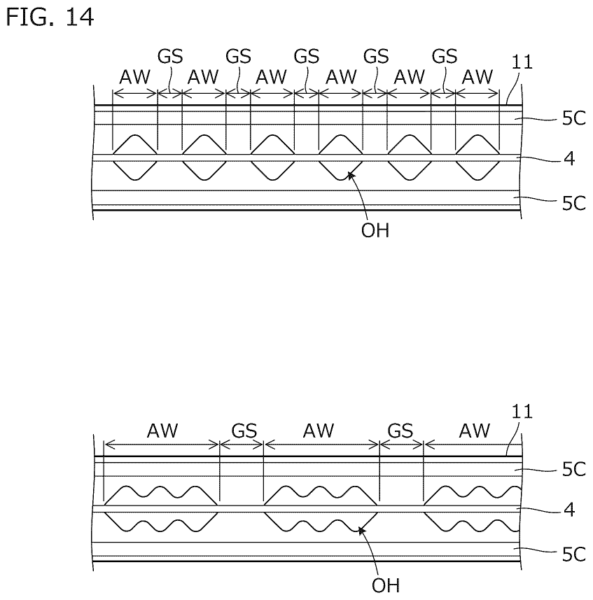

The diagram illustrated in the upper portion of FIG. 14 is a plan view of the first resin layer 11 of the high-frequency signal transmission line as an example. The lower portion of FIG. 14 is a plan view of the first resin layer 11 (the first resin layer on which the signal conductor pattern 4 is located) of the high-frequency signal transmission line in which the shape of the hollow portion and the arrangement pitch thereof are different from those of the upper example.

In the example illustrated in the upper portion of FIG. 14, a plurality of openings OH each including rounded corners in a diamond pattern are located in the first resin layer 11. The width of the opening OH in the extending direction of the signal conductor pattern 4 is AW, and the interval between the openings OH in the extending direction of the signal conductor pattern 4 is GS. As described above, the larger the value of AW/GS, the higher the rate at which the signal conductor pattern 4 passes through the hollow portion, so that the dielectric loss due to the relative permittivity and the dielectric loss tangent of the resin layer is reduced.

Comparing the example illustrated in the upper portion of FIG. 14 with the example illustrated in the upper portion of FIG. 13, even if the value of AW/GS is the same, the planar area and the volume of the opening OH can be reduced, so that the strength of the hollow portion by the opening OH is maintained, and the effect of further reducing the risk of breakage in the vicinity of the hollow portion is enhanced.

In the example illustrated in the lower portion of FIG. 14, an opening OH having a shape in which three diamond patterns overlap with each other while being shifted by a certain distance in the extending direction of the signal conductor pattern 4 is formed in the first resin layer 11. The width of the opening OH in the extending direction of the signal conductor pattern 4 is AW, and the interval between the openings OH is GS. Also in the case of the opening OH having such a shape, similarly to the example illustrated in (3) of FIG. 13, since the long axis of the opening OH is along the extending direction of the signal conductor pattern 4, the lengthening efficiency of the opening OH with respect to the enlargement of the planar area of the opening OH is high.

In the twelfth example embodiment, a high-frequency signal transmission line in which upper and lower portions of a stacked resin body are recessed will be exemplified.

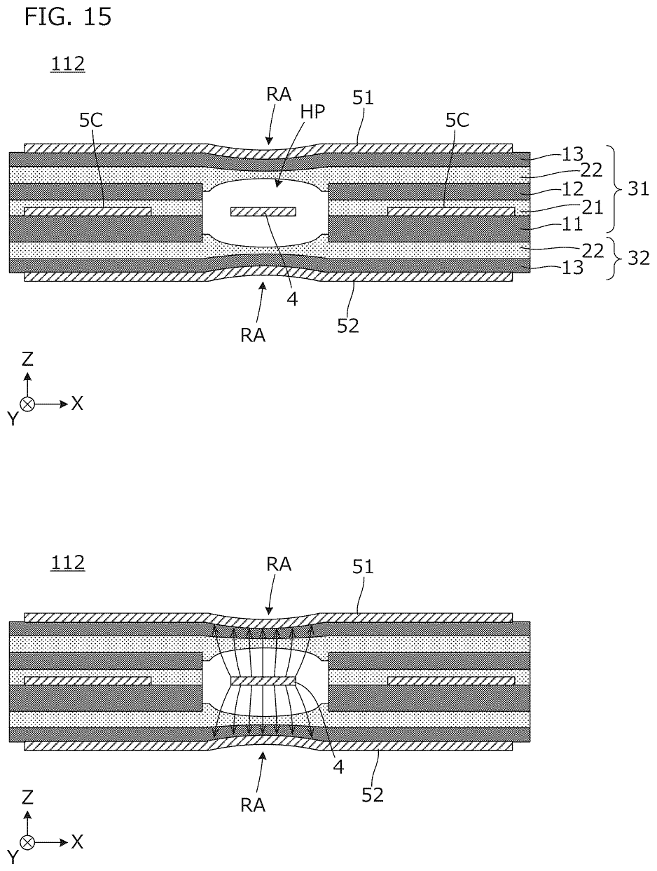

The upper portion of FIG. 15 is a cross-sectional view of a high-frequency signal transmission line 112 according to the present example embodiment. The lower part of FIG. 15 is a cross-sectional view of the high-frequency signal transmission line 112 illustrating a state of the electric field distribution by the lines of electric force. The high-frequency signal transmission line 112 includes an upper resin stacked portion 31, a lower resin stacked portion 32, a signal conductor pattern 4, a first ground conductor layer 51, a second ground conductor layer 52, and a ground conductor pattern 5C. The other basic structures are similar to those of the high-frequency signal transmission line 109 illustrated in FIG. 11.

Unlike the example illustrated in FIG. 3, in the high-frequency signal transmission line 112 of the present example embodiment, a concave portion RA is formed such that the upper and lower sides of the hollow portion HP in the resin stacking direction are recessed. The high-frequency signal transmission line 112 is pressed in a state where the first ground conductor layer 51 is attached to the first resin layer 13 at the time of manufacturing to form the concave portion RA.

The high-frequency signal transmission line 112 of the present example embodiment has the following functions and effects.

(a) It is difficult for any object to hit the vicinity of the hollow portion HP from the outside of the high-frequency signal transmission line 112, and as a result, it is possible to prevent deformation of the hollow portion HP and the periphery thereof.

(b) Since the resin layer in the vicinity of the hollow portion HP has a cross-sectional arch shape, deformation of the hollow portion HP and the periphery thereof can be effectively reduced or prevented.

Needless to say, also in the present example embodiment, as illustrated in FIG. 3, there may be an interlayer connection conductor protruding to the outside of the stacked resin body.

In the high-frequency signal transmission line 112 of the present example embodiment, an arrow drawn so as to jump out from the signal conductor pattern 4 in the lower portion of FIG. 15 is a notable line of electric force. As described above, an electric field is generated between the signal conductor pattern 4 and the first ground conductor layer 51 and between the signal conductor pattern 4 and the second ground conductor layer 52. As illustrated in this drawing, the closer to both ends of the signal conductor pattern 4, that is, the farther from the center of the signal conductor pattern 4, the longer the lines of electric force from the signal conductor pattern 4 to the first ground conductor layer 51 and the second ground conductor layer 52 become.

In the signal conductor pattern 4, the current density increases toward both ends thereof due to the edge effect (skin effect) of conductors. However, according to the above configuration, the electric field intensity is reduced or prevented toward both ends of the signal conductor pattern 4, so that the current distribution in the signal conductor pattern 4 is averaged. As a result, the conductor loss due to the signal conductor pattern 4 is relaxed.

In the thirteenth example embodiment, a high-frequency signal transmission line including a protective film on an outer surface will be exemplified.

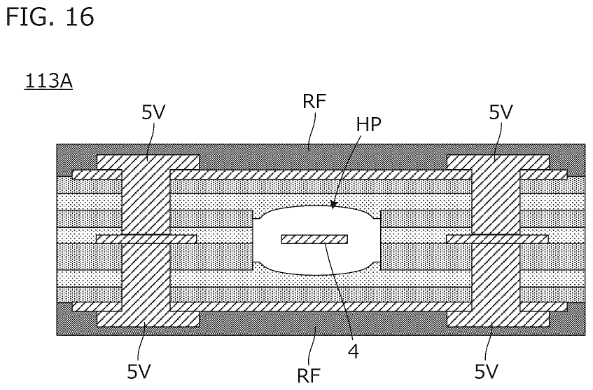

FIG. 16 is a longitudinal cross-sectional view of a high-frequency signal transmission line 113A formed by forming a resist film on the high-frequency signal transmission line 109 illustrated in FIG. 11.

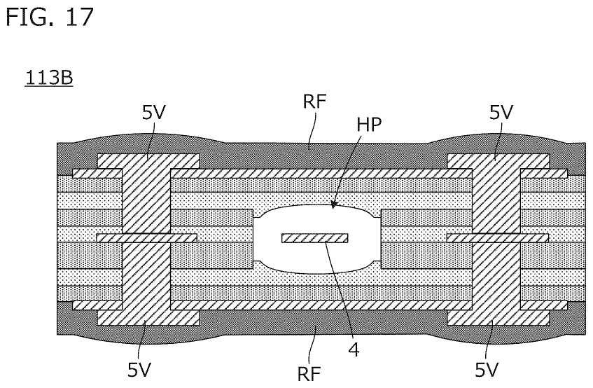

FIG. 17 is a longitudinal cross-sectional view of a high-frequency signal transmission line 113B formed by forming a resist film on the high-frequency signal transmission line 109 illustrated in FIG. 11.

A resist film RF illustrated in FIGS. 16 and 17 is a resist film obtained by applying a resist resin to the front and back of the high-frequency signal transmission line 109 illustrated in FIG. 11 and then curing the resist resin.

As described above, by providing the resist film RF on the outer surface, the stress applied to the high-frequency signal transmission lines 113A and 113B from the outside is relaxed by the resist film RF, and the decrease in the strength of the high-frequency signal transmission line due to the presence of the hollow portion HP is further reduced or prevented.

In the high-frequency signal transmission line 113A illustrated in FIG. 16, even if some object abuts from the outside, the stress received by the resist film RF is concentrated on the interlayer connection conductor 5V, so that the hollow portion HP is protected.

As illustrated in FIG. 17, if the resist film RF protrudes at the protruding portion of the interlayer connection conductor 5V, it is difficult for any object to hit the vicinity of the hollow portion HP from the outside of the high-frequency signal transmission line 113B due to the presence of these protrusions, so that deformation of the hollow portion HP and the periphery thereof can be prevented.

In the fourteenth example embodiment, a high-frequency signal transmission line in which the structures of the upper and lower outer surfaces of the hollow portion are different from those of the examples described above will be exemplified.

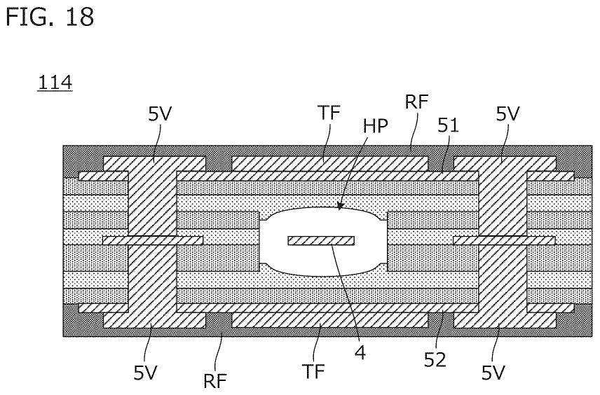

FIG. 18 is a longitudinal cross-sectional view of a high-frequency signal transmission line 114 according to the fourteenth example embodiment. In this example, a thickened portion TF is formed by increasing the plating thickness of the region overlapping the hollow portion HP in the first ground conductor layer 51 and the second ground conductor layer 52 as viewed in the stacking direction of the layers. Plating in this region may be performed simultaneously with plating for forming the interlayer connection conductor 5V.

According to the present example embodiment, the strength of the upper and lower portions of the hollow portion HP in the stacked body is effectively enhanced. As a result, deformation of the hollow portion HP can be more effectively reduced or prevented.

An example of an electronic device will be described in the fifteenth example embodiment.

The high-frequency signal transmission line of the present invention can be used as a high-frequency signal transmission line in various electronic devices. For example, connectors are provided in the respective high-frequency circuits located on the two circuit boards, and for example, the coaxial connectors 61 and 62 of the high-frequency signal transmission line 101 illustrated in FIG. 1 are connected. The circuit board and the high-frequency signal transmission line 101 are housed in a housing having a predetermined shape. The electronic device is configured in this manner.

Finally, the present invention is not limited to each example embodiment described above. Modifications and alterations can be appropriately made by those skilled in the art. The scope of the present invention is defined not by the above-described example embodiments but by the claims. Further, the scope of the present invention includes modifications and alterations from the example embodiments within the scope equivalent to the claims.

For example, in each example embodiment, the high-frequency signal transmission line including a single signal conductor pattern is shown, but a plurality of signal conductor patterns may be provided.

In addition, two or more signal conductor patterns may be provided to constitute a differential line. Example embodiments of the present invention can also be applied to a form in which a plurality of signal conductor patterns of the differential line is arranged in one hollow portion.

In addition, the plurality of signal conductor patterns may be arranged in the layer direction of each resin layer, or may be arranged in the stacking direction of the resin layers.

In addition, in each example embodiment, the rectangular high-frequency signal transmission line is illustrated as viewed from the stacking direction of the resin layers, but this shape is arbitrary.

In each example embodiment, the high-frequency signal transmission line including the linear signal conductor pattern is illustrated, but the signal conductor pattern may be curved or partially curved as viewed from the stacking direction of the resin layers.

In each example embodiment, the high-frequency signal transmission line having a planar shape is illustrated, but the stacked surface of each resin layer may be, for example, a curved surface such as a cylindrical surface or a partially curved surface. Further, for example, an entirety or a portion may be a torsional curved surface.

In order to bond the copper foil defining the ground conductor layer and the first resin layer, another resin layer different from the first resin layer and the second resin layer may be provided.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A high-frequency signal transmission line comprising:
a resin stacked portion in which a single or a plurality of first resin layers and a single or a plurality of second resin layers are stacked, a signal conductor pattern in contact with at least a single first resin layer of the single or the plurality of first resin layers, and a ground conductor layer facing the signal conductor pattern with a portion or an entirety of the resin stacked portion interposed therebetween; wherein
a hollow portion is provided in the resin stacked portion at an opening in at least the single first resin layer of the first resin layers at a position along the signal conductor pattern in the resin stacked portion; and
the second resin layer in contact with the first resin layer in which the opening is located adheres to a portion of an end surface in the opening of the first resin layer.

2. The high-frequency signal transmission line according to claim 1, wherein
the ground conductor layer includes a first ground conductor layer and a second ground conductor layer existing on both sides of the signal conductor pattern in a direction of the stacking; and
the resin stacked portion exists as an upper resin stacked portion and a lower resin stacked portion on both sides with respect to the signal conductor pattern in a direction of the stacking.

3. The high-frequency signal transmission line according to claim 2, further comprising:
an interlayer connection conductor that electrically connects the first ground conductor layer and the second ground conductor layer; wherein
the first ground conductor layer, the second ground conductor layer, the upper resin stacked portion, the lower resin stacked portion, the signal conductor pattern, and the interlayer connection conductor define a transmission line.

4. The high-frequency signal transmission line according to claim 3, wherein the interlayer connection conductor includes a protruding portion protruding outward from the first ground conductor layer, and the interlayer connection conductor includes a protruding portion protruding outward from the second ground conductor layer.

5. The high-frequency signal transmission line according to claim 4, further comprising a third resin layer covering a protruding portion of the interlayer connection conductor, on an outer surface of the upper resin stacked portion or the lower resin stacked portion.

6. The high-frequency signal transmission line according to claim 1, wherein the second resin layer in contact with the first resin layer in which the opening is located, since a maximum thickness and a minimum thickness of the second resin layer are different in the opening located in the first resin layer, adheres to a portion of an end surface in the opening of the first resin layer.

7. The high-frequency signal transmission line according to claim 1, wherein a portion of the hollow portion in the second resin layer is a curved surface in which a vicinity of a center expands outward of the hollow portion as compared with a periphery of the hollow portion.

8. The high-frequency signal transmission line according to claim 1, wherein the second resin layer has a Young's modulus lower than a Young's modulus of the first resin layer at normal temperature.

9. The high-frequency signal transmission line according to claim 1, wherein a resin material of the second resin layer is a resin material having a lower dielectric constant and a lower dielectric loss tangent than a resin material of the first resin layer.

10. The high-frequency signal transmission line according to claim 1, wherein a portion of the second resin layer that is located in a direction of stacking to the opening of the first resin layer and defines the hollow portion with the first resin layer has an arch shape.

11. The high-frequency signal transmission line according to claim 1, wherein the second resin layer in contact with the first resin layer in which the opening is located protrudes into the opening, and a thickness of the second resin layer is greater in a region of the opening than in other regions.

12. The high-frequency signal transmission line according to claim 1, wherein the opening of the second resin layer is located in the opening of the first resin layer, and the hollow portion is defined by the opening of the first resin layer and the opening of the second resin layer.

13. The high-frequency signal transmission line according to claim 1, wherein a maximum width of the hollow portion is larger than a width of the signal conductor pattern.

14. The high-frequency signal transmission line according to claim 1, wherein the hollow portion overlaps with the signal conductor pattern when viewed in a direction of stacking, and is located between the signal conductor pattern and the ground conductor layer.

15. The high-frequency signal transmission line according to claim 1, further comprising additional hollow portions in the resin stacked portion at the first opening or the second opening.

16. The high-frequency signal transmission line according to claim 14, wherein a total number of the hollow portions is six.

17. The high-frequency signal transmission line according to claim 14, wherein an interval between adjacent pairs of the hollow portions is about 1/4 wavelength of a transmission signal transmitted by the high-frequency signal transmission line.

18. The high-frequency signal transmission line according to claim 1, wherein a stacked surface of each resin layer is a curved surface, a cylindrical surface, a partially curved surface, or a torsional curved surface.

19. The high-frequency signal transmission line according to claim 1, wherein the signal conductor pattern is linear, curved, partially curved or has a planar shape.

20. An electronic device comprising the high-frequency signal transmission line according to claim 1.
